(19) United States
(12) Patent Application Publication
(10) Pub. No.: US 2021/0404056 A1
(43) Pub. Date: Dec. 30, 2021

(54) ULTRA-THIN FILMS WITH TRANSITION METAL DICHALCOGENIDES

(71) Applicant: Applied Materials, Inc., Santa Clara, CA (US)

(72) Inventors: Susmit Singha Roy, Sunnyvale, CA (US); Abhijit Basu Mallick, Palo Alto, CA (US)

(73) Assignee: Applied Materials, Inc., Santa Clara, CA (US)

(21) Appl. No.: 16/913,398

(22) Filed: Jun. 26, 2020

(51) Int. Cl. C23C 16/30; C23C 16/455; C23C 16/02; H01L 21/768

(52) U.S. Cl. CPC C23C 16/305; H01L 21/76841; C23C 16/0281; C23C 16/45595

(57) ABSTRACT

Methods for selectively forming a transition metal dichalcogenide (TMDC) film comprise exposing a substrate comprising a silicon oxide-based surface and a tungsten (W) segment to a sulfur source to selectively form the transition metal dichalcogenide film with the tungsten segment relative to the silicon oxide-based surface. Chemical vapor deposition (CVD) at a temperature in a range of 350° C. to 600° C. is used to form the TMDC film. CVD may be conducted by low pressure CVD (LPCVD) or atmospheric pressure CVD (APCVD). Methods of making devices incorporating the TMDC films are also provided.

### TECHNICAL FIELD

Embodiments of the present disclosure pertain to the field of electronic devices and methods and apparatus for manufacturing electronic devices. More particularly, embodiments of the disclosure provide transition metal dichalcogenide films, which are suitable as thin barrier layers.

### BACKGROUND

Semiconductor technology has advanced at a rapid pace and device dimensions have shrunk with advancing technology to provide faster processing and storage per unit space. As semiconductor technology advances, the market demands increasing smaller chips with increasingly more structures per unit area.

Reducing the size of integrated circuits (ICs) results in improved performance, increased capacity, and/or reduced cost. Each size reduction requires more sophisticated techniques to form the ICs. Shrinking transistor size, for example, allows for the incorporation of an increased number of memory or logic devices on a chip, lending to the fabrication of products with increased capacity.

With respect to liners and barriers, due to scaling of dimensions in devices, the liners and barriers are being scaled to <20-25 Å thickness, which can make currently used liners and barriers discontinuous, which in-turn affects power consumption, yield, and reliability of the electronic device.

Accordingly, there is an ongoing need in the art for ultra-thin films without compromising barrier performance and conductivity.

### SUMMARY

One or more embodiments of the disclosure are directed to methods of selectively forming a transition metal dichalcogenide (TMDC) film. A substrate comprising a dielectric or semiconductor surface and a transition metal segment is exposed to a chalcogen to selectively form the transition metal dichalcogenide film with the transition metal segment relative to the dielectric or semiconductor surface. Chemical vapor deposition (CVD) at a temperature in a range of 350° C. to 600° C. is used to form the TMDC film. CVD may be conducted by low pressure CVD (LPCVD) or atmospheric pressure CVD (APCVD).

Additional embodiments of the disclosure are directed to methods of selectively forming a transition metal dichalcogenide (TMDC) film. A substrate comprising a silicon oxide-based surface and a tungsten (W) segment is exposed to a sulfur source to selectively form the transition metal dichalcogenide film with the tungsten segment relative to the silicon oxide-based surface. Chemical vapor deposition (CVD) at a temperature in a range of 350° C. to 600° C. is used to form the TMDC film. CVD may be conducted by low pressure CVD (LPCVD) or atmospheric pressure CVD (APCVD).

Additional embodiments of the disclosure are directed to methods of making a device. A substrate comprising a dielectric or semiconductor surface and a transition metal segment is exposed to a chalcogen to selectively form the transition metal dichalcogenide film with the transition metal segment relative to the dielectric or semiconductor surface. Chemical vapor deposition (CVD) at a temperature in a range of 350° C. to 600° C. is used to form the TMDC film. CVD may be conducted by low pressure CVD (LPCVD) or atmospheric pressure CVD (APCVD). Thereafter, the substrate is exposed to a material to form a material film, wherein the transition metal dichalcogenide film is a barrier between the dielectric or semiconductor surface and the material film. The material may be a gate material. The material may be an interconnect material.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIGS. 1A-1B show schematic representations of a substrate in accordance with one or more embodiments of the disclosure at different stages during production; and

FIG. 2 illustrates a flowchart of a method in accordance with one or more embodiments of the disclosure.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

As used in this specification and the appended claims, the term “substrate” refers to a surface, or portion of a surface, upon which a process acts. It will also be understood by those skilled in the art that reference to a substrate can also refer to only a portion of the substrate, unless the context clearly indicates otherwise. Additionally, reference to depositing on a substrate can mean both a bare substrate and a substrate with one or more films or features deposited or formed thereon.

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, amorphous silicon, doped silicon, germanium, gallium arsenide, glass, sapphire, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate, anneal, UV cure, e-beam cure and/or bake the substrate surface. In addition to film processing directly on the surface of the substrate itself, in the present disclosure, any of the film processing steps disclosed may also be performed on an underlayer formed on the substrate as disclosed in more detail below, and the term “substrate surface” is intended to include such underlayer as the context indicates. Thus for example, where a film/layer or partial film/layer has been deposited onto a substrate surface, the exposed surface of the newly deposited film/layer becomes the substrate surface.

One or more embodiments of the disclosure advantageously provide methods for selectively forming transition metal dichalcogenide (TMDC) films at low temperatures, e.g., 350° C. to 600° C., during chemical vapor deposition (CVD) processes. These films are ultra-thin, e.g., 5 Å to 30 Å. The TMDC films possess long range order and lamellar structure, resulting in a 2D material. Due to the long range order and small interatomic distance, the 2D material is a superior barrier compared to currently used barriers such as TaN, TiN (used in back-end-of-the-line BEOL) or TiN, AlOx (used in 3D NAND). Such films would be suitable to replace any metal liner or barriers used in other integration flows. The 2D TMDC films herein advantageously are ultra-thin continuous films (<20 Å) that do not compromise on barrier performance or conductivity. These ultra-thin films are suitable for 3D NAND, DRAM, logic devices, and the like.

In an exemplary non-limiting embodiment, a process sequence comprises: (1) first depositing a transition metal on a substrate, the substrate having a dielectric or semiconductor surface; (2) thereafter exposing the substrate to a chalcogen during a CVD process at a temperature in a range 350° C. to 600° C. and a pressure that is atmospheric or below; (3) reacting the chalcogen with the transition metal to form a transition metal dichalcogenide (TMDC) film. Further, a material may be deposited onto the TMDC film to form a material film, wherein the TMDC film is a barrier between the dielectric or semiconductor surface and the material film.

Experiments showed that when a silicon oxide substrate with a tungsten segment was exposed to sulfur, a tungsten sulfide film selectively formed over the silicon oxide surface during an atmospheric chemical vapor deposition (CVD) process. No growth was observed on the silicon oxide surface. The tungsten sulfide film had a 2D layered structure.

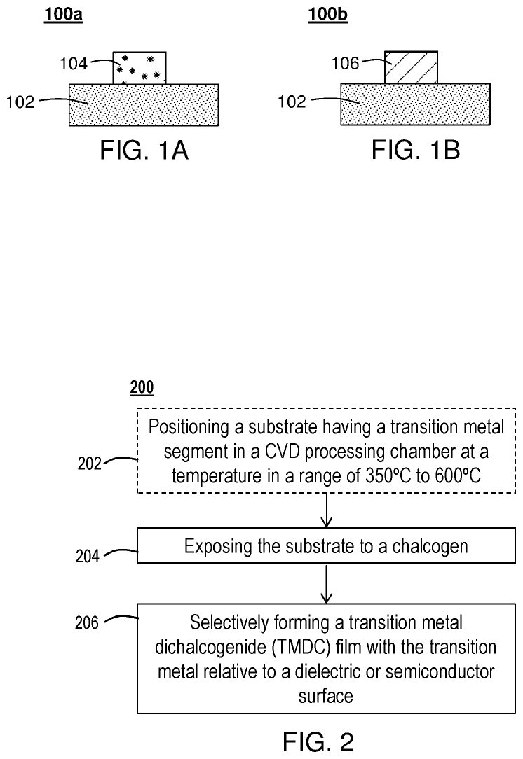

In FIGS. 1A-1B a substrate of one or more embodiments of the disclosure is shown at different stages during production. In FIG. 1A, a substrate 100a comprises a dielectric or semiconductor surface 102 and a transition metal segment 104. It is understood that additional layers may be present between the dielectric or semiconductor surface 102 and the transition metal segment 104. The number of layers and their content may vary according to a design of the device.

In one or more embodiments, the surface 102 comprises a dielectric material. The dielectric material may be chosen from the group consisting of: carbon (C), silicon nitride (SiN), silicon oxide (SiO), silicon oxynitride (SiON), silicon oxycarbide (SiOC), silicon carbide (SiC), or a high-k dielectric. The high-k dielectric may include aluminum oxide or hafnium oxide.

In one or more embodiments, the surface 102 comprises a semiconductor material, e.g., silicon (Si), carbon (C), germanium (Ge), silicon germanium (SiGe), gallium arsenide (GaAs), indium phosphate (InP), indium gallium arsenide (InGaAs), indium aluminum arsenide (InAlAs), copper indium gallium selenide (CIGS), other semiconductor materials, or any combination thereof. In one or more embodiments, the semiconductor material comprises one or more of silicon (Si), germanium (Ge), gallium (Ga), arsenic (As), indium (In), phosphorus (P), copper (Cu), or selenium (Se). Although a few examples of materials from which the substrate surface 102 may be formed are described herein, any material that may serve as a foundation upon which passive and active electronic devices (e.g., transistors, memories, capacitors, inductors, resistors, switches, integrated circuits, amplifiers, optoelectronic devices, or any other electronic devices) may be built falls within the spirit and scope of the present disclosure.

A transition metal of the transition metal segment 104 may include any known transition metal. In one or more embodiments, the transition metal is selected from the group consisting of: tungsten (W), molybdenum (Mo), tantalum (Ta), niobium (Nb), vanadium (V), hafnium (Hf), zirconium (Zr), titanium (Ti), rhenium (Re), ruthenium (Ru), cobalt (Co), platinum (Pt), palladium (Pd), and combinations thereof.

Formation of the transition metal segment is conducted by any suitable process known to the skilled artisan, including, but not limited to atomic layer deposition (ALD), chemical vapor deposition (CVD), physical vapor deposition (PVD), or other metal deposition techniques known to the skilled artisan.

Referring to FIG. 1B, upon exposure to a chalcogen, the transition metal of the transition metal segment selectively reacts to form a transition metal dichalcogenide (TMDC) film 106 on the dielectric or semiconductor surface 102. There is no film growth on the dielectric or semiconductor surface 102. The TMDC film has a 2D crystal structure.

In one or more embodiments, the TMDC film has a thickness in a range of 5 Å to 30 Å, including all values and subranges therebetween, including less than 25 Å, less than 20 Å, less than 15 Å, and less than 10 Å.

In one or more embodiments, the chalcogen is selected from the group consisting of: sulfur (S), selenium (Se), tellurium (Te), and combinations thereof.

In some embodiments, the substrate 100a or 100b has at least one feature formed thereon. In one or more embodiments, the feature is selected from one or more of a trench, a via, a fin, or a peak.

FIG. 2 illustrates a method 200 in accordance with one or more embodiments for selectively forming a transition metal dichalcogenide (TMDC) film. At operation 202, a substrate is positioned in a CVD processing chamber. The substrate has a transition metal thereon, for example, in a transition metal segment. The CVD process is operated at a temperature range of 350° C. to 600° C., including all values and subranges therebetween, including 350° C. to 550° C., 350° C. to 500° C., 350° C. to 450° C., and 350° C. to 400° C. The CVD process is operated at atmospheric pressure (APCVD) or low pressure (e.g., below atmospheric) (LPCVD).

In an embodiment, the transition metal segment is formed prior to exposing the substrate to the chalcogen. The transition metal may be deposited from a gaseous transition metal precursor to form a transition metal segment in a CVD processing chamber. The transition metal may be supplied as a solid after having been processed elsewhere and then provided for further processing to form the TMDC film.

At operation 204, the substrate is exposed to the chalcogen. In one or more embodiments, the chalcogen is supplied as a powder, which is sublimed during the CVD process. For example, sulfur power may be supplied to an APCVD furnace, over which carrier gases, including but not limited to hydrogen and/or argon, flow. Alternatively, the chalcogen is supplied as a gaseous precursor, for example, H₂S, which flows over the transition metal located on the substrate surface in the chamber.

At operation 206, the chalcogen, e.g., sublimed sulfur or a sulfur precursor, reacts with the transition metal located on the substrate surface in the chamber to selectively form the TMDC film.

Thereafter, the substrate may be exposed to a material to form a material film. Where present, the transition metal dichalcogenide film is a barrier between the dielectric or semiconductor surface and the material film.

In an embodiment, the material is a gate material. The gate material may be selected from the group consisting of: tungsten (W), copper (Cu), cobalt (Co), aluminum (Al), ruthenium (Ru), iridium (Ir), molybdenum (Mo), platinum (Pt), tantalum (Ta), titanium (Ti), rhodium (Rh), nickel (Ni), and combinations thereof.

In a non-limiting liner application, a TMDC film is a continuous thin liner to facilitate (i) nucleation of subsequent metal, (ii) help with adhesion of metal to underlying dielectrics and (iii) help block diffusion of impurities in transition metal precursors to an underlying dielectric (e.g., F that is present in a W precursor). With shrinking node sizes, real estate shortage for metal resulting in increased resistivity in the metal gate of 3D NAND is a challenge. As an example, current liners require at least 25 Å of TiN on which the W metal is grown. The TMCD films are continuous at lower thicknesses compared to other liner materials.

Further, TMDC films have better carrier mobility compared to the current polySi in the 3D NAND devices, and advantageously can improve device performance.

In an embodiment, the material is an interconnect material. The interconnect material may be selected from the group consisting of: copper (Cu), cobalt (Co), ruthenium (Rh), and combinations thereof.

In a non-limiting conventional flow application, the TMDC film can advantageously be a continuous barrier between Cu and Co and a low-k dielectric to mitigate and/or prevent electromigration of Cu/Co. This addresses difficulties with current barriers of TaN (for Cu) and TiN (for Co), which are discontinuous below 20-25 Å.

In a non-limiting subtractive flow application in BEOL, deposition of a metal occurs first, followed by metal etch to form metal lines/interconnects. A TMDC film is grown around the metal lines/interconnects. A low-k dielectric material is deposited in gaps between the metal lines/interconnects. Any excess low-k dielectric is polished off using CMP. In this scheme the barrier will be grown after the metal etch and before the dielectric deposition.

Various hardware arrangements can be used to implement the method 200. In some embodiments, one or two chambers can be applied to achieve multiple processes. A chamber can be used for deposition of the transition metal. Another chamber can be used for forming the TMDC film. Or, the process can be performed in one chamber.

Additional embodiments of the disclosure are directed to a processing system for executing the methods described herein.

Generally, a cluster tool is a modular system comprising multiple chambers which perform various functions including substrate center-finding and orientation, degassing, annealing, deposition and/or etching. According to one or more embodiments, a cluster tool includes at least a first chamber and a central transfer chamber. The central transfer chamber may house a robot that can shuttle substrates between and among processing chambers and load lock chambers. The transfer chamber is typically maintained at a vacuum condition and provides an intermediate stage for shuttling substrates from one chamber to another and/or to a load lock chamber positioned at a front end of the cluster tool. Two well-known cluster tools which may be adapted for the present disclosure are the Centura® and the Endura®, both available from Applied Materials, Inc., of Santa Clara, Calif. However, the exact arrangement and combination of chambers may be altered for purposes of performing specific portions of a process as described herein. Other processing chambers which may be used include, but are not limited to, cyclical layer deposition (CLD), atomic layer deposition (ALD), chemical vapor deposition (CVD), physical vapor deposition (PVD), etch, pre-clean, chemical clean, thermal treatment such as RTP, plasma nitridation, degas, orientation, hydroxylation and other substrate processes. By carrying out processes in a chamber on a cluster tool, surface contamination of the substrate with atmospheric impurities can be avoided without oxidation prior to depositing a subsequent film.

At least one controller may be coupled to one or both of the first chamber and the central transfer chamber. In some embodiments, there is more than one controller connected to the individual chambers or stations, and a primary control processor is coupled to each of the separate processors to control the system. The controller may be one of any form of general-purpose computer processor, microcontroller, microprocessor, etc., that can be used in an industrial setting for controlling various chambers and sub-processors.

The at least one controller can have a processor, a memory coupled to the processor, input/output devices coupled to the processor, and support circuits to communication between the different electronic components. The memory can include one or more of transitory memory (e.g., random access memory) and non-transitory memory (e.g., storage).

The memory, or computer-readable medium, of the processor may be one or more of readily available memory such as random access memory (RAM), read-only memory (ROM), floppy disk, hard disk, or any other form of digital storage, local or remote. The memory can retain an instruction set that is operable by the processor to control parameters and components of the system. The support circuits are coupled to the processor for supporting the processor in a conventional manner. Circuits may include, for example, cache, power supplies, clock circuits, input/output circuitry, subsystems, and the like.

Processes may generally be stored in the memory as a software routine that, when executed by the processor, causes the process chamber to perform processes of the present disclosure. The software routine may also be stored and/or executed by a second processor that is remotely located from the hardware being controlled by the processor. Some or all of the methods of the present disclosure may also be performed in hardware. As such, the process may be implemented in software and executed using a computer system, in hardware as, e.g., an application specific integrated circuit or other type of hardware implementation, or as a combination of software and hardware. The software routine, when executed by the processor, transforms the general purpose computer into a specific purpose computer (controller) that controls the chamber operation such that the processes are performed.

In some embodiments, the controller has one or more configurations to execute individual processes or sub-processes to perform the method. The controller can be connected to and configured to operate intermediate components to perform the functions of the methods. For example, the controller can be connected to and configured to control one or more of gas valves, actuators, motors, slit valves, vacuum control, etc.

The controller of some embodiments has one or more configurations selected from: a configuration to move a substrate on the robot between the plurality of processing chambers and metrology station; a configuration to load and/or unload substrates from the system; a configuration to move a substrate between and among the central transfer station and processing chambers.

One or more embodiments are directed to a non-transitory computer readable medium including instructions, that, when executed by a controller of a processing chamber, cause the processing chamber to perform the operations of positioning a substrate having a transition metal segment in a CVD processing chamber, setting a temperature in a range of 350° C. to 600° C., operating at atmospheric pressure or applying a vacuum to operate a low pressure below atmospheric pressure, and exposing the substrate to a chalcogen. A selective transition metal dichalcogenide (TMDC) film is formed with the transition metal relative to a dielectric or semiconductor surface of the substrate.

In an embodiment, the non-transitory computer readable medium further includes instructions, that, when executed by a controller of a processing chamber, cause the processing chamber to perform the operation of exposing the substrate to a material to form a material film, wherein the transition metal dichalcogenide film is a barrier between the dielectric or semiconductor surface and the material film.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. Furthermore, the particular features, structures, materials, or characteristics may be combined in any suitable manner in one or more embodiments.

Although the disclosure herein has been described with reference to particular embodiments, those skilled in the art will understand that the embodiments described are merely illustrative of the principles and applications of the present disclosure. It will be apparent to those skilled in the art that various modifications and variations can be made to the method and apparatus of the present disclosure without departing from the spirit and scope of the disclosure. Thus, the present disclosure can include modifications and variations that are within the scope of the appended claims and their equivalents.

What is claimed is:

1. A method of selectively forming a transition metal dichalcogenide (TMDC) film, the method comprising:
exposing a substrate comprising a dielectric or semiconductor surface and a transition metal segment to a chalcogen to selectively form the transition metal dichalcogenide film with the transition metal segment relative to the dielectric or semiconductor surface by chemical vapor deposition (CVD) at a temperature in a range of 350° C. to 600° C.

2. The method of claim 1, wherein CVD is conducted by low pressure CVD (LPCVD) or atmospheric pressure CVD (APCVD).

3. The method of claim 1, wherein the transition metal dichalcogenide film has a 2D crystal structure.

4. The method of claim 1, wherein the transition metal dichalcogenide film has a thickness in a range of 5 Å to 30 Å.

5. The method of claim 1, wherein a transition metal of the transition metal segment is selected from the group consisting of: tungsten (W), molybdenum (Mo), tantalum (Ta), niobium (Nb), vanadium (V), hafnium (Hf), zirconium (Zr), titanium (Ti), rhenium (Re), ruthenium (Ru), cobalt (Co), platinum (Pt), palladium (Pd), and combinations thereof.

6. The method of claim 1, wherein the transition metal is supplied as a solid.

7. The method of claim 1, wherein the transition metal is deposited from a gaseous transition metal precursor.

8. The method of claim 1, wherein the transition metal segment is formed prior to exposing the substrate to the chalcogen.

9. The method of claim 1, wherein the chalcogen is selected from the group consisting of: sulfur (S), selenium (Se), tellurium (Te), and combinations thereof.

10. The method of claim 1, wherein the chalcogen is supplied as a powder.

11. The method of claim 1, wherein the chalcogen is supplied as a gaseous precursor.

12. The method of claim 1, wherein the dielectric surface comprises one or more of the following dielectric materials: carbon (C), silicon nitride (SiN), silicon oxide (SiO), silicon oxynitride (SiON), silicon oxycarbide (SiOC), silicon carbide (SiC), or a high-k dielectric.

13. The method of claim 1, wherein the semiconductor surface comprises one or more of the following semiconductor materials: silicon (Si), germanium (Ge), or silicon germanium (SiGe).

14. A method of selectively forming a transition metal dichalcogenide (TMDC) film, the method comprising:
exposing a substrate comprising a silicon oxide-based surface and a tungsten (W) segment to a sulfur (S) source to selectively form the TMDC film comprising a tungsten sulfide with the tungsten segment relative to the silicon oxide-based surface by chemical vapor deposition (CVD) at a temperature in a range of 350° C. to 600° C.

15. The method of claim 14, wherein CVD is conducted by low pressure CVD (LPCVD) or atmospheric pressure CVD (APCVD).

16. The method of claim 14, wherein the transition metal dichalcogenide film has a 2D crystal structure.

17. The method of claim 14, wherein the film comprising the transition metal dichalcogenide has a thickness in a range of 5 Å to 30 Å.

18. A method of making a device, the method comprising:
exposing a substrate comprising a dielectric or semiconductor surface and a transition metal segment to a chalcogen to selectively form a transition metal dichalcogenide (TMDC) film with the transition metal segment relative to the dielectric surface by chemical vapor deposition (CVD) at a temperature in a range of 350° C. to 600° C., wherein the transition metal dichalcogenide film has a thickness in a range of 5 Å to 30 Å;
exposing the substrate to a material to form a material film, wherein the transition metal dichalcogenide film is a barrier between the dielectric or semiconductor surface and the material film.

19. The method of claim 18, wherein the material is a gate material selected from the group consisting of: tungsten (W), copper (Cu), cobalt (Co), aluminum (Al), ruthenium (Ru), iridium (Ir), molybdenum (Mo), platinum (Pt), tantalum (Ta), titanium (Ti), rhodium (Rh), nickel (Ni), and combinations thereof.

20. The method of claim 18, wherein the material is an interconnect material selected from the group consisting of: copper (Cu), cobalt (Co), ruthenium (Rh), and combinations thereof.
